(19) United States
(12) Patent Application Publication
(10) Pub. No.: US 2021/0273118 A1
(43) Pub. Date: Sep. 2, 2021

(54) Semiconductor Device

(71) Applicant: KABUSHIKI KAISHA TOKAI-RIKA-DENKI-SEISAKUSHO, Niwa-gun, Aichi-ken (JP)

(72) Inventor: Yoshikazu Kataoka, Niwa-gun, Aichi-ken (JP)

(21) Appl. No.: 17/260,590

(22) PCT Filed: Jul. 8, 2019
(86) PCT No.: PCT/JP2019/027014

§ 371 Date: Jan. 15, 2021

(30) Foreign Application Priority Data
Jul. 18, 2018 (JP) 2018-135261

(51) Int. Cl. H01L 29/861; H01L 29/06

(52) U.S. Cl. CPC H01L 29/8611; H01L 29/0615

(57) ABSTRACT

A semiconductor device includes a protected element, an element isolation region, and a first connection section. The protected element is configured including a diode between an anode region and a cathode region, and is arranged in an active layer of a substrate including the active layer formed over a conductive substrate-support with an insulation layer interposed between the active layer and the substrate-support. The element isolation region includes a trench, an insulation body, and a conductor. The trench extends from a surface of the active layer as far as the insulation layer and surrounds a periphery of the diode. The insulation body is arranged on a side wall of the trench. The conductor fills the trench such that the insulation body is interposed between the conductor and the trench. The first connection section electrically connects the cathode region of the diode and the conductor of the element isolation region.

### TECHNICAL FIELD

The present invention relates to a semiconductor device, and in particular to effective technology applicable to a semiconductor device including a protected element.

### BACKGROUND ART

Japanese Patent No. 4354876 discloses a semiconductor device adopting a silicon on insulator (SOI) substrate. The SOI substrate is formed as a layered structure including a silicon substrate, a buried oxide film on the silicon substrate, and a p-type active layer on the buried oxide film. A metal-oxide-semiconductor field-effect transistor (MOSFET) is formed on the p-type active layer.

Generally a silicon substrate of a SOI substrate is either in a floating state not applied with an electrical potential, or a ground potential is applied to the silicon substrate.

However, in cases in which a p-n junction diode having a high withstand voltage structure is formed on the p-type active layer of the SOI substrate as a protected element, an element isolation region is arranged surrounding the periphery of the p-n junction diode so as to electrically isolate the p-n junction diode from other elements. A trench isolation structure that reliably isolates the p-n junction diode from other elements is favorably employed as an element isolation region. Such an element isolation region is configured including a trench that extends from a surface of a p-type active layer to a buried oxide film, a silicon oxide film that is formed to side walls of the trench, and a polycrystalline silicon film that fills the trench such that the silicon oxide film is interposed between the polycrystalline silicon film and the trench.

However, when a p-n junction diode is surrounded by such an element isolation region, a region of the p-type active layer following the trench of the element isolation region forms a region where a depletion layer does not spread toward the p-type active layer from the element isolation region side. Thus, if a positive surge voltage is applied to the cathode region, a surge current flowing into the p-type active layer from the cathode region flows into the anode region along a current path in this region where the depletion layer does not spread. There is accordingly room for improvement from the perspective of increasing the withstand voltage of the p-n junction diode.

### SUMMARY OF INVENTION

### Technical Problem

In consideration of the above circumstances, the present invention provides a semiconductor device capable of easily increasing a withstand voltage of a protected element.

### Solution to Problem

A semiconductor device according to a first aspect of the present invention includes a protected element configured including a p-n junction diode between an anode region and a cathode region, and arranged in an active layer of a substrate including the active layer formed over a conductive substrate-support with an insulation layer interposed between the active layer and the substrate-support, an element isolation region configured including a trench extending from a surface of the active layer as far as the insulation layer and surrounding a periphery of the p-n junction diode, an insulation body arranged on a side wall of the trench, and a conductor filling the trench such that the insulation body is interposed between the conductor and the trench, and a first connection section electrically connecting the cathode region to the conductor.

The semiconductor device according to the first aspect includes the protected element and the element isolation region on the substrate.

The substrate includes the conductive substrate-support, the insulation layer on the substrate-support, and the active layer on the insulation layer. The protected element is arranged in the active layer, and is configured including the p-n junction diode between the anode region and the cathode region.

The element isolation region is configured including the trench, the insulation body, and the conductor. The trench surrounds the periphery of the p-n junction diode, and extends from the surface of the active layer as far as the insulation layer. The insulation body is arranged on a side wall of the trench. The conductor fills the trench such that the insulation body is interposed between the conductor and the trench.

The semiconductor device further includes the first connection section. The first connection section electrically connects the cathode region of the p-n junction diode to the conductor of the element isolation region.

Supposing a positive surge voltage were to be applied to the cathode region, then this surge voltage would also be applied to the conductor of the element isolation region. A field plate structure is constructed by the active layer of the substrate, and the insulation body and the conductor of the element isolation region. When a surge voltage is applied, due to the field plate effect a depletion layer spreads toward the active layer side from an interface between the active layer and the insulation body at the side wall of the trench, thereby enabling a current path following the trench between the anode region and the element isolation region to be eliminated. This enables surge current to be effectively suppressed from flowing into the anode region through a current path from the cathode region. In addition thereto, an electric field occurring at the p-n junction between the cathode region and the anode region due to spreading of the depletion layer can be effectively alleviated.

The simple configuration electrically connecting the cathode region of the p-n junction diode to the conductor of the element isolation region thereby enables the junction withstand voltage of the p-n junction diode to be increased.

A semiconductor device according to a second aspect of the present invention is the semiconductor device according to the first aspect, wherein the first connection section is configured by wiring arranged on the cathode region and on the conductor.

In the semiconductor device according to the second aspect, the first connection section is configured by wiring. This wiring is arranged on the cathode region of the p-n junction diode and on the conductor of the element isolation region, and is formed using part of wiring that electrically connects the p-n junction diode to another element.

There is therefore no need to incorporate another wiring layer in the semiconductor device or in the fabrication process of the semiconductor device, since an existing wiring layer can be used to electrically connect the cathode region to the conductor. This thereby enables the first connection section to be realized by a simple configuration.

A semiconductor device according to a third aspect of the present invention is the semiconductor device according to the first aspect or the second aspect, further including a second connection section electrically connecting the cathode region to the substrate-support.

The semiconductor device according to the third aspect further includes the second connection section. The second connection section electrically connects the cathode region of the p-n junction diode to the substrate-support of the substrate.

Supposing a positive surge voltage were to be applied to the cathode region, then this surge voltage would also be applied to the substrate-support. A field plate structure is constructed by the substrate-support, the insulation layer, and the active layer of the substrate. When a surge voltage is applied to the substrate-support, a depletion layer formed at the p-n junction between the anode region and the cathode region due to the field plate effect spreads, thus alleviating an electric field occurring at the p-n junction. This accordingly enables the junction withstand voltage of the p-n junction diode to be increased without setting a lower impurity concentration in the active layer.

A semiconductor device according to a fourth aspect of the present invention is the semiconductor device according to the third aspect, further including a semiconductor element arranged in the active layer in a separate region to the protected element, the semiconductor element being any one out of an insulated-gate field-effect transistor, a bipolar transistor, a diffusion resistor, or a metal-insulator-semiconductor capacitor.

In the semiconductor device according to the fourth aspect, the semiconductor element is arranged in the active layer in a separate region to the protected element. The semiconductor element is at least one out of an insulated-gate field-effect transistor, a bipolar transistor, a diffusion resistor, or a metal-insulator-semiconductor capacitor. Since the junction withstand voltage of the p-n junction diode can be increased without setting a lower impurity concentration in the active layer, the characteristics of the semiconductor element are not altered.

A semiconductor device according to a fifth aspect of the present invention is the semiconductor device according to the third aspect or the fourth aspect, further including an external terminal arranged on the substrate and electrically connected to the cathode region, a die pad or wiring board mounted with the substrate and electrically connected to the substrate-support, and a lead electrically connected to the external terminal through a wire. The second connection section is configured including a path electrically connecting the lead either to the die pad or to the wiring board.

The semiconductor device according to the fifth aspect further includes the external terminal, the die pad or wiring board, and the lead. The external terminal is arranged on the substrate, and is electrically connected to the cathode region. The die pad or wiring board is mounted with the substrate, and is electrically connected to the substrate-support of the substrate. The lead is electrically connected to the external terminal through the wire. Note that the second connection section is configured including a path electrically connecting the lead either to the die pad or to the wiring board.

Thus, supposing a surge voltage were to be applied to the cathode region from the lead through the wire and the external terminal, the surge voltage can also be applied to the substrate-support from the lead through the die pad or wiring board. This enables an increase in the junction withstand voltage of the p-n junction diode to be simply achieved by exploiting the field plate effect.

A semiconductor device according to a sixth aspect of the present invention is the semiconductor device according to the third aspect or the fourth aspect, wherein the second connection section includes a penetrating section extending from a surface of the insulation layer to the substrate-support so as to be in communication with the insulation layer side of the trench, and a penetrating conductor filling the penetrating section such that one end portion of the penetrating conductor is electrically connected to the conductor and another end portion of the penetrating conductor is electrically connected to the substrate-support. The second connection section is configured including a path including the penetrating conductor.

In the semiconductor device according to the sixth aspect, the second connection section includes the penetrating section and the penetrating conductor. The penetrating section extends from the surface of the insulation layer to the substrate-support so as to be in communication with the insulation layer side of the trench. The penetrating conductor fills the penetrating section. The one end portion of the penetrating conductor is electrically connected to the conductor in the trench, and the other end portion of the penetrating conductor is electrically connected to the substrate-support. The second connection section is configured including a path including the penetrating conductor.

Thus, supposing a surge voltage were to be applied to the cathode region, the surge voltage would also be applied to the conductor filling the trench of the element isolation region, and moreover the surge voltage would also be applied to the substrate-support of the substrate through the penetrating conductor filling the penetrating section. This enables an increase in the junction withstand voltage of the p-n junction diode to be simply achieved by exploiting the field plate effect.

In addition thereto, the surge voltage can be instantly applied to the substrate-support via a short path that is in close proximity to the p-n junction diode due to utilizing the conductor of the element isolation region that is arranged surrounding the periphery of the p-n junction diode.

### Advantageous Effects of Invention

The present invention is capable of providing a semiconductor device capable of easily increasing a withstand voltage of a protected element.

### BRIEF DESCRIPTION OF DRAWINGS

FIG. 1 is a vertical cross-section structural diagram schematically illustrating an enlargement of relevant portions of a semiconductor device according to a first exemplary embodiment of the present invention.

FIG. 2 is a vertical cross-section structural diagram corresponding to FIG. 1 and illustrating a semiconductor device according to a comparative example.

FIG. 3 is a vertical cross-section structural diagram corresponding to FIG. 1 and schematically illustrating an enlargement of relevant portions of a semiconductor device according to a second exemplary embodiment of the present invention.

FIG. 4 is a cross-section illustrating a packaging structure of a semiconductor device according to the second exemplary embodiment.

FIG. 5 is a vertical cross-section structural diagram corresponding to FIG. 1 and schematically illustrating an enlargement of relevant portions of a semiconductor device according to a third exemplary embodiment of the present invention.

### DESCRIPTION OF EMBODIMENTS

### First Exemplary Embodiment

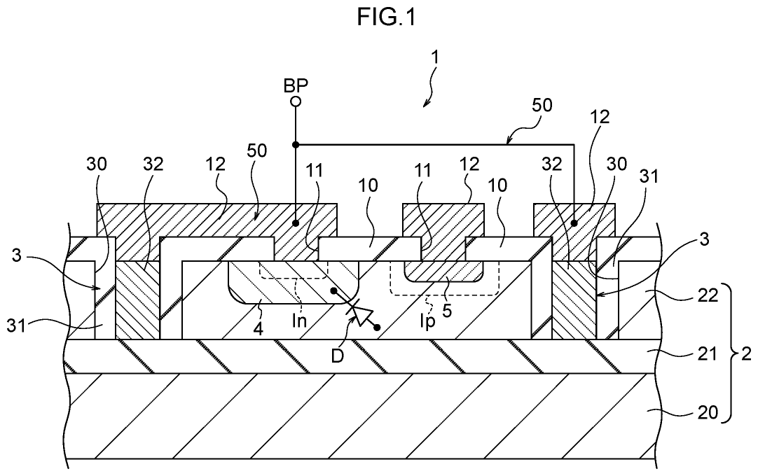

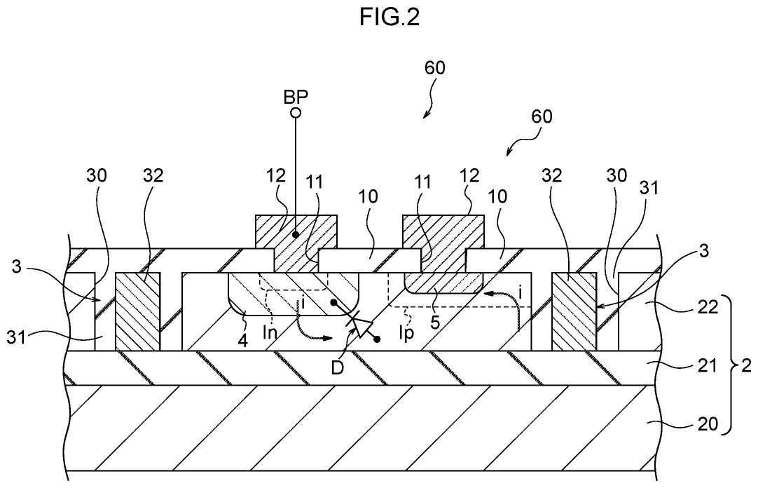

Explanation follows regarding a semiconductor device according to a first exemplary embodiment of the present invention, with reference to FIG. 1 and FIG. 2.

Semiconductor Device 1 Substrate Cross-Section Structure

As illustrated in FIG. 1, a semiconductor device 1 according to the present exemplary embodiment is principally configured by a substrate (a semiconductor pellet or a semiconductor chip) 2. A p-n junction diode D (hereafter simply referred to as the diode D), serving as a protected element, is arranged on a portion on a main face of the substrate 2. The diode D is electrically connected to an external terminal BP by connecting in the reverse direction.

A SOI substrate is employed as the substrate 2. Namely, the substrate 2 has a structure of sequentially stacked layers of a conductive substrate-support 20, an insulation layer 21 formed on the substrate-support 20, and an active layer 22 formed on the insulation layer 21.

In this example, the substrate-support 20 is formed by a monocrystalline silicon substrate set as p-type with low impurity concentration doping. Note that the substrate-support 20 may be set as p-type with medium or high impurity concentration doping, or alternatively may be set as n-type.

The insulation layer 21 is formed by a buried oxide (BOX) film, and more specifically is formed by a silicon oxide film. The insulation layer 21 is for example formed using an ion implantation method in which oxygen is implanted into the substrate-support 20 so as to cause localized oxidation of silicon in the substrate-support 20.

In this example, the active layer 22 is, similarly to the substrate-support 20, formed by a monocrystalline silicon substrate set as p-type with low impurity concentration doping. The active layer 22 is formed using part of a surface layer of the substrate-support 20, and forming the insulation layer 21 creates a partition (electrically isolates) between the active layer 22 and the substrate-support 20 about the insulation layer 21 as a boundary. The diode D is arranged in the active layer 22, and another circuit-configuring semiconductor element other than the diode D is also arranged in the active layer 22. Note that configuration of this semiconductor element will be explained in a second exemplary embodiment, described later.

Element Isolation Region 3 Structure

An element isolation region 3 configuring a region surrounding the periphery of the diode D is arranged in the active layer 22. The element isolation region 3 is configured so as to electrically isolate between elements, such as between the diode D and the semiconductor element other than the diode D. In the present exemplary embodiment, the element isolation region 3 is configured including a trench 30, an insulation body 31, and a conductor 32, and is configured as what is referred to as a trench isolation structure.

The trench 30 surrounds the periphery of the diode D, and is configured so as to extend from the surface of the active layer 22 at least as far as the surface of the insulation layer 21. The trench 30 is set so as to have a smaller groove opening width dimension than groove depth dimension (so as to have a large aspect ratio). Namely, adopting the element isolation region 3 including the trench 30 reduces the surface area occupied by the element isolation region 3 on the surface of the active layer 22, thereby enabling the integration density of the semiconductor device 1 to be improved. The trench 30 may be formed by anisotropic etching such as reactive-ion etching (RIE) during a fabrication process of the semiconductor device 1.

The insulation body 31 is arranged at side walls of the trench 30, and is for example formed by a silicon oxide film. The silicon oxide film may for example be formed using a chemical vapor deposition (CVD) method.

The conductor 32 fills the inside of the trench 30 with the insulation body 31 interposed between the conductor 32 and the trench 30. For example, a polycrystalline silicon film doped with impurities so as to be adjusted to a low resistance value may be employed as the conductor 32. In the fabrication process, a polycrystalline silicon film may for example be filled into the trench 30 by deposition using a CVD method until the polycrystalline silicon film configures a flat surface over the active layer 22. The polycrystalline silicon film over the active layer 22 is then removed, leaving the inside of the trench 30 completely filled. The removal of the polycrystalline silicon may be performed by employing an etching method or a chemical mechanical polishing (CMP) method.

Diode D Structure

The diode D is configured with a p-n junction between the p-type active layer 22 serving as an anode region and an n-type semiconductor region 4 serving as a cathode region. The n-type semiconductor region 4 is formed by introducing n-type impurities into the active layer 22 from the surface thereof using an ion implantation method or a solid phase diffusion method, and activating the n-type impurities. The impurity concentration of the n-type semiconductor region 4 is set higher than the impurity concentration of the active layer 22.

A p-type semiconductor region 5 of the same conductivity type as the active layer 22 is arranged on a portion of the main face of the active layer 22 serving as the anode region. The p-type semiconductor region 5 is set with a higher impurity concentration than the impurity concentration of the n-type semiconductor region 4. Thus arranging the p-type semiconductor region 5 enables a reduction in contact resistance between the active layer 22, serving as the anode region, and wiring that is electrically connected thereto (wiring 12 illustrated in FIG. 1) to be achieved.

A passivation film 10 is arranged over the entire surface of the substrate 2, including over the diode D and over the element isolation region 3. The passivation film 10 is for example formed of a monolayer configured by a silicon oxide film or a silicon nitride film, or a composite film configured of these films stacked together.

The wiring 12 is arranged on the passivation film 10. Although the wiring 12 is illustrated as a monolayer wiring structure, a wiring structure of two or more layers may be employed. For example, an aluminum alloy film to which copper (Cu) and silicon (Si) has been added is employed as the wiring 12. One end portion of one line of the wiring 12 is electrically connected to the n-type semiconductor region 4 serving as a cathode region through a connection hole 11 formed penetrating the passivation film 10 in its film thickness direction. The other end portion of this wiring 12 is connected to the external terminal BP. One end portion of another line of the wiring 12 is electrically connected to the p-type active layer 22 serving as an anode region through the p-type semiconductor region 5. The other end portion of this wiring 12 is connected to internal circuitry, not illustrated in the drawings.

Structure of First Connection Section 50

A first connection section (first connection structure) 50 that electrically connects the n-type semiconductor region 4 serving as the cathode region to the conductor 32 of the element isolation region 3 is arranged in the semiconductor device 1 configured as described above. To explain in more detail, as described above, the wiring 12 is electrically connected to the n-type semiconductor region 4, and part of the wiring 12 is led out onto the element isolation region 3 in order to construct the first connection section 50. This part of the wiring 12 is electrically connected at an upper portion of the trench 30 of the element isolation region 3 through the connection hole 11 formed in the passivation film 10. Thus, all of the conductor 32 of the element isolation region 3 surrounding the periphery of the diode D is electrically shorted with the n-type semiconductor region 4.

Note that although the first connection section 50 is electrically connected to all of the conductor 32 of the element isolation region 3 surrounding the periphery of the diode D in this example, it is sufficient that that the first connection section 50 be electrically connected to the conductor 32 of the element isolation region 3 at least where arranged along a periphery of the p-type semiconductor region 5.

Moreover, if more than one connection location is present between the first connection section 50 and the conductor 32, these plural locations may be provided at a prescribed spacing along a length direction of the trench 30.

Operation and Advantageous Effects of Present Exemplary Embodiment

As illustrated in FIG. 1, the semiconductor device 1 according to the present exemplary embodiment includes the protected element in the substrate 2, and the element isolation region 3.

The substrate 2 includes the conductive substrate-support 20, the insulation layer 21 on the substrate-support 20, and the active layer 22 on the insulation layer 21. The protected element is arranged in the active layer 22 and is configured including the diode D between the anode region and the cathode region.

The element isolation region 3 is configured including the trench 30, the insulation body 31, and the conductor 32. The trench 30 surrounds the periphery of the diode D and extends from the surface of the active layer 22 as far as the insulation layer 21. The insulation body 31 is arranged on the side walls of the trench 30. The conductor 32 fills the trench 30 with the insulation body 31 interposed between the conductor 32 and the trench 30.

The semiconductor device 1 further includes the first connection section 50. The first connection section 50 electrically connects the n-type semiconductor region 4 (cathode region) of the diode D to the conductor 32 of the element isolation region 3.

Supposing a positive surge voltage were to be applied to the cathode region from the external terminal BP, then this surge voltage would also be applied to the conductor 32 of the element isolation region 3 through the first connection section 50. A field plate structure is constructed by the active layer 22 of the substrate 2, and the insulation body 31 and the conductor 32 of the element isolation region 3. When a surge voltage is applied, a depletion layer In spreads toward the cathode region side from the p-n junction between the cathode region (n-type semiconductor region 4) and the anode region (p-type active layer 22). A depletion layer Ip also spreads toward the anode region side from the p-n junction. Since the surge voltage applied to the cathode region is also applied to the conductor 32 of the element isolation region 3, due to the field plate effect the depletion layer Ip also spreads toward the active layer 22 side from an interface between the active layer 22 and the insulation body 31 at side faces of the trench 30. Namely, the depletion layer Ip spreads as far as the anode region, in particular as far as an intermediate portion between the p-type semiconductor region 5 and the element isolation region 3, enabling a current path for a surge current i (see FIG. 2) following the trench 30 of the active layer 22 to be eliminated.

FIG. 2 illustrates a semiconductor device 60 according to a comparative example in which the first connection section 50 of the present exemplary embodiment is not provided. In the semiconductor device 60 according to the comparative example, when a positive surge voltage is similarly applied to the cathode region from the external terminal BP, the depletion layer In spreads toward the cathode region side from the p-n junction between the cathode region and the anode region. The depletion layer Ip also spreads toward the anode region side from the p-n junction.

However, a region in which the depletion layer Ip does not spread arises between the anode region, in particular the p-type semiconductor region 5, and the element isolation region 3. Thus, the surge current i flowing into the active layer 22 from the cathode region flows along a current path running along an interface between the active layer 22 and the insulation layer 21, and also along the trench 30 of the active layer 22 at an interface between the active layer 22 and the insulation body 31. The surge current i flows into the p-type semiconductor region 5 as a result, such that the junction withstand voltage of the diode D cannot be increased.

In the semiconductor device 1 according to the present exemplary embodiment as illustrated in FIG. 1, the current path of the surge current i can be eliminated as described above, enabling the surge current i to be effectively suppressed from flowing into the anode region through a current path from the cathode region. In addition thereto, an electric field occurring at the p-n junction between the cathode region and the anode region due to spreading of the depletion layer Ip can be effectively alleviated.

This enables the junction withstand voltage of the diode D to be increased by a simple configuration to electrically connect the cathode region of the diode D and the conductor 32 of the element isolation region 3.

In other words, a field plate structure can be simply constructed by a simple configuration in which the element isolation region 3 is used to cause an electrical short circuit between the cathode region of the diode D and the conductor 32 of the element isolation region 3. Namely, the field plate structure can actually be constructed simply using the element isolation region 3, enabling the withstand voltage of the diode D to be increased as a result, without the need for additional fabrication processes of the semiconductor device 1 in order to construct a field plate structure.

Moreover, as illustrated in FIG. 1, in the semiconductor device 1 according to the present exemplary embodiment the first connection section 50 is configured by the wiring 12. The wiring 12 is arranged on the cathode region (n-type semiconductor region 4) of the diode D and on the conductor 32 of the element isolation region 3, and the first connection section 50 is formed using the part of the wiring 12 that electrically connects the diode D to another element.

There is therefore no need to incorporate another wiring layer in the semiconductor device 1 or in the fabrication process of the semiconductor device 1, since the existing wiring layer can be used to electrically connect the cathode region to the conductor 32. This thereby enables the first connection section 50 to be realized by a simple configuration.

### Second Exemplary Embodiment

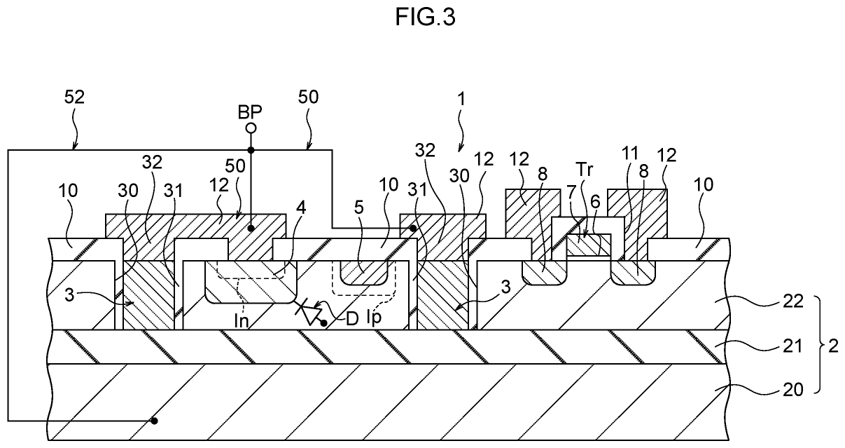

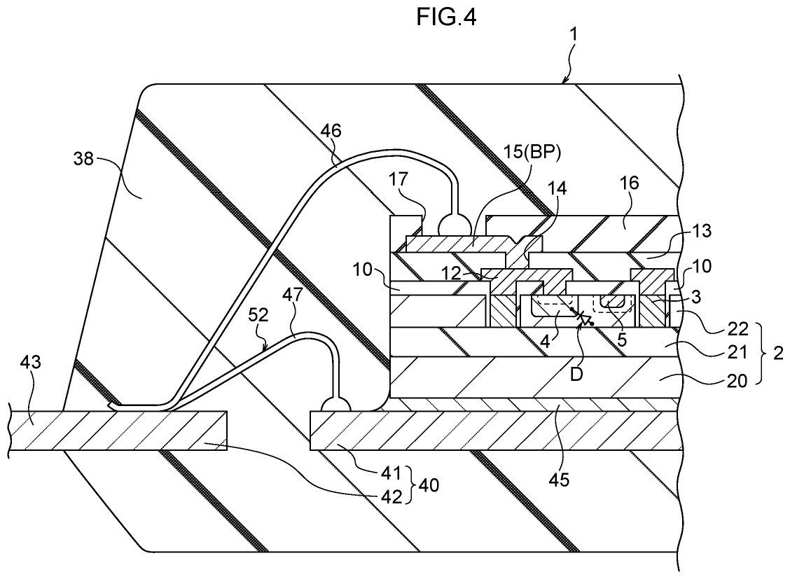

Next, explanation follows regarding a semiconductor device 1 according to a second exemplary embodiment of the present invention, with reference to FIG. 3 and FIG. 4. Note that in the second exemplary embodiment and in a third exemplary embodiment, described later, configuration elements that are the same or basically the same as configuration elements in the first exemplary embodiment are appended with the same reference numerals, and duplicate explanation thereof is omitted.

Semiconductor Device 1 Substrate Cross-Section Structure

As illustrated in FIG. 3, a semiconductor device 1 according to the present exemplary embodiment includes a semiconductor element other than the diode D serving as the protected element provided in the active layer 22 of the substrate 2, and also includes a second connection section 52.

The other semiconductor element is arranged in the active layer 22 of the substrate 2 in a separate region to the diode D. Note that configuration of an element isolation region 3 is the same as configuration of the element isolation region 3 according to the first exemplary embodiment.

Although there is no particular limitation thereto, in this example, an insulated-gate field-effect transistor Tr (IGFET; hereafter simply referred to as the transistor Tr) is arranged as the semiconductor element. Note that use of the term IGFET encompasses both MOSFET and metal-insulator-semiconductor field-effect transistors (MISFET).

Structure of Transistor Tr

The transistor Tr is arranged on the main face of the active layer 22 within a region peripherally surrounded by the element isolation region 3. The transistor Tr is configured including the active layer 22 employed as a channel forming region, n-type semiconductor regions 8 that form a pair of main electrodes that respectively serve as a source region and a drain region, a gate insulation film 6, and a gate electrode 7.

The pair of n-type semiconductor regions 8 are arranged on the main face of the active layer 22 with a spacing in a gate width direction therebetween. Although the n-type semiconductor regions 8 have the opposite conductivity type to the p-type semiconductor region 5, the n-type semiconductor regions 8 are set with a similar level of impurity concentration to the p-type semiconductor region 5. A region of the active layer 22 between the pair of n-type semiconductor regions 8 is employed as a channel forming region.

The gate insulation film 6 is at least formed between the pair of n-type semiconductor regions 8 on the main face of the active layer 22. A monolayer film configured of a silicon oxide film, or a stacked composite film including a silicon oxide film and a silicon nitride film, may be employed as the gate insulation film 6.

The gate electrode 7 is arranged on the gate insulation film 6. For example, a monolayer film configured from a polycrystalline silicon film doped with impurities so as to be adjusted to a low resistance value, or a stacked composite film including a high-melting-point metal film or a high-melting-point metal-silicide film on a polycrystalline silicon film, may be employed as the gate electrode 7.

The transistor Tr configured in this manner is thereby set to n-channel conductivity type. Note that in the present exemplary embodiment a non-illustrated p-channel conductivity type transistor is also arranged in the active layer 22 so as to construct a pair of complementary transistors.

The wiring 12 is electrically connected to the n-type semiconductor regions 8 of the transistor Tr. The wiring 12 is arranged on the passivation film 10. Similarly to the respective connection structures between the wiring 12 and the n-type semiconductor region 4 and p-type semiconductor region 5 of the diode D, the wiring 12 is electrically connected to the n-type semiconductor regions 8 through connection holes 11 formed in the passivation film 10.

Semiconductor Device 1 Packaging Structure

As illustrated in FIG. 4, a first layer passivation film 10, a first layer wiring 12, as well as a second layer passivation film 13, a second layer wiring 15, and a third layer passivation film 16 not illustrated in FIG. 3 are respectively arranged in this sequence on the substrate 2. Although a dual layer wiring structure including the wiring 12 and the wiring 15 is adopted in the semiconductor device 1 in the present exemplary embodiment, a monolayer wiring structure or a wiring structure of three or more layers may be adopted.

The first layer passivation film 10 is formed over the entire surface of the substrate 2, including over the diode D, over the transistor Tr illustrated in FIG. 3, and over the element isolation region 3. The passivation film 10 is formed of the same material as the passivation film 10 described in the first exemplary embodiment. The passivation film 10 is formed with a main purpose of keeping the first layer wiring 12 electrically isolated from the diode D, the transistor Tr, and so on.

The first layer wiring 12 is formed of the same material as the wiring 12 described in the first exemplary embodiment.

The second layer passivation film 13 is formed over the passivation film 10, including over the wiring 12. The passivation film 13 is, for example, formed of a similar material to the passivation film 10.

The second layer wiring 15 having a prescribed wiring pattern is arranged over the passivation film 13. One end portion of the wiring 15 is connected to the other end portion of the wiring 12 connected to the n-type semiconductor region 4 and the conductor 32 of the element isolation region 3 through a connection hole 14 formed penetrating the passivation film 13 in its film thickness direction. The other end portion of the wiring 15 configures the external terminal BP. An upper face of the external terminal BP is exposed inside a bonding opening 17 formed penetrating in the film thickness direction through the third layer passivation film (final passivation film) 16 arranged over the passivation film 13 including over the wiring 15.

The passivation film 13 and the passivation film 16 are for example formed of a similar material to the passivation film 10. Similarly, the wiring 15 may be formed of a similar material to the wiring 12.

As illustrated in FIG. 4, the semiconductor device 1 further includes a lead 40, the substrate 2, a bonding wire 46, and a encapsulation resin 38. More specifically, the lead 40 is configured including a die pad (tab) 31, an inner lead 42, and an outer lead 33.

The substrate 2 is bonded onto the die pad 41 through a bonding material 45. A back face of the substrate-support 20 of the substrate 2 is disposed so as to oppose an upper face of the die pad 41. For example, a silver (Ag) paste is employed as the bonding material 45. Namely, the die pad 41 is electrically connected to the substrate-support 20.

The inner lead 42 is laid in the in-plane direction of the die pad 41 at a periphery of the die pad 41. The inner lead 42 is arranged inside the encapsulation resin 38. One end portion on the die pad 41-side of the inner lead 42 is electrically connected to the external terminal BP (the wiring 15) of the substrate 2 through the bonding wire 46.

The outer lead 33 is integrally formed to the other end portion of the inner lead 42 so as to lead outside the encapsulation resin 38. Although not illustrated in the drawings, the outer lead 33 conforms to a structure for mounting the semiconductor device 1 to a mounting substrate, and is molded into the shape of a terminal-insertion or surface-mounting lead.

The die pad 41, the inner lead 42, and the outer lead 33 are formed by being molded and cut out from a lead frame, not illustrated in the drawings. A sheet material such as, for example, an iron-nickel (Fe—Ni) alloy or a copper (Cu) alloy is employed for the lead 40. Gold (Au) or nickel (Ni) plating is performed on the surface of the lead 40 at join regions and bonding regions of the lead 40 to enhance bonding performance.

Moreover, an Au wire may, for example, be employed as the bonding wire 46.

The encapsulation resin 38 is molded by a resin molding method using an epoxy-based resin material.

Second Connection Section 52 Structure

As is schematically illustrated in FIG. 3, in addition to the first connection section 50, the semiconductor device 1 includes the second connection section (connecting structure) 52 to electrically connect the n-type semiconductor region 4, configuring the cathode region of the diode D serving as the protected element, to the substrate-support 20 of the substrate 2.

To explain in more detail with reference to FIG. 4, the second connection section 52 of the present exemplary embodiment is configured including the wiring 12, the wiring 15, the bonding wire 46, the bonding material 45, the die pad 41, and a bonding wire 47. Namely, the second connection section 52 includes a signal path through which a signal flows from the inner lead 42 to the n-type semiconductor region 4 via the bonding wire 46, the external terminal BP, the wiring 15, and the wiring 12, and includes a short circuit path allowing the inner lead 42 to short circuit to the substrate-support 20 through the bonding wire 47, the die pad 41, and the bonding material 45. The bonding wire 47 is electrically connected between the inner lead 42 and the die pad 41, and is formed by a similar material to the bonding wire 46.

Due to provision of the second connection section 52 configured in this manner, when a positive surge voltage from the outer lead 33 is applied (input) to the cathode region of the diode D through the external terminal BP, a similar positive surge voltage is also applied to the substrate-support 20 through the die pad 41.

Operation and Advantageous Effects of Present Exemplary Embodiment

The semiconductor device 1 according to the present exemplary embodiment is capable of obtaining similar operation and advantageous effects to the operation and advantageous effects obtained by the semiconductor device 1 according to the first exemplary embodiment.

The semiconductor device 1 according to the present exemplary embodiment further includes the second connection section 52. The second connection section 52 electrically connects between the cathode region (n-type semiconductor region 4) of the diode D and the substrate-support 20 of the substrate 2.

Supposing a positive surge voltage were to be applied to the cathode region of the diode D, then this surge voltage would also be applied to the substrate-support 20. The substrate 2 is constructed with a field plate structure including the substrate-support 20, the insulation layer 21, and the active layer 22. When a surge voltage is applied to the substrate-support 20, an electric field effect is generated in the active layer 22 due to the field plate effect, such that a depletion layer Ip formed at the p-n junction between the anode region and the cathode region spreads, alleviating an electric field occurring at the p-n junction. This accordingly enables the junction withstand voltage of the diode D to be increased without setting a lower impurity concentration in the active layer 22.

Since there is no need to set a lower impurity concentration in the active layer 22, the withstand voltage of the transistor Tr with respect to a surge voltage in the protected element can be increased without the affecting the characteristics of the transistor Tr by for example altering the threshold voltage or altering the parasitic capacitance thereof.

In other words, employing the substrate 2 having a SOI structure and adopting a simple configuration to electrically short circuit between the cathode region of the diode D and the substrate-support 20 enables a field plate structure to be easily constructed. Namely, the withstand voltage of the diode D can actually be increased without adding a fabrication process to the semiconductor device 1 to construct a field plate structure on the surface of the active layer 22.

Moreover, as illustrated in FIG. 4, the second connection section 52 in the semiconductor device 1 according to the present exemplary embodiment is configured to electrically connect the cathode region (n-type semiconductor region 4) to a region of the substrate-support 20 opposing the diode D.

In other words, at least the substrate-support 20 should be short circuited to the cathode region, particularly at a region opposing the p-n junction between the anode region and the cathode region of the diode D. In particular, a sheet resistance value of the substrate-support 20 is high in cases in which there is a low impurity concentration set for the substrate-support 20, and so any surge voltage is preferably applied to the substrate-support 20 at a region near to the diode D.

In the semiconductor device 1 configured in this manner, when for example a positive surge voltage is applied to the cathode region of the diode D, the surge voltage is immediately applied to the region of the substrate-support 20 opposing the diode D. An electric field occurring at the p-n junction of the diode D is accordingly immediately alleviated, enabling the junction withstand voltage of the diode D to be increased.

Furthermore, as illustrated in FIG. 3, in the semiconductor device 1 according to the present exemplary embodiment, the transistor Tr is arranged in a different region to that of the diode D in the active layer 22 of the substrate 2. Since the junction withstand voltage of the diode D can be increased without setting a lower impurity concentration in the active layer 22, the characteristics of the transistor Tr are not altered.

Note that alterations to the characteristics of a semiconductor element can be suppressed even in cases in which, instead of the transistor Tr, there is one or more element out of a bipolar transistor, a diffusion resistor, or a metal insulator semiconductor (MIS) capacitor arranged as the semiconductor element.

For example, in the case of a bipolar transistor, there is no need to set a lower impurity concentration for the active layer 22, and so there is no alteration to the parasitic capacitance applied to an operation region. Moreover, for example, in the case of a diffusion resistor formed by an n-type semiconductor region, a depletion layer occurring at the p-n junction between the diffusion resistor and the active layer 22 can be suppressed from spreading, and so there is no alteration to the parasitic capacitance applied to the diffusion resistor. Furthermore, in the case of an MIS capacitor, a depletion layer can be suppressed from spreading, and so there is also no alteration to the parasitic capacitance applied to the capacitor.

Moreover, as illustrated in FIG. 4, the semiconductor device 1 according to the present exemplary embodiment further includes the external terminal BP (wiring 15), the die pad 41, and the lead 40. The external terminal BP is electrically connected to the cathode region (n-type semiconductor region 4) of the diode D arranged on the substrate 2. The die pad 41 is mounted to the substrate 2 and electrically connected to the substrate-support 20 of the substrate 2. The lead 40 is electrically connected to the external terminal BP through the bonding wire 46. Note that the second connection section 52 in this example is configured with the lead 40 and the die pad 41 electrically connected.

Thus, supposing a positive surge voltage were to be applied from the lead 40 to the cathode region via the bonding wire 46 and the external terminal BP (through the signal path), a positive surge voltage could simply be applied to the substrate-support 20 from the lead 40 via the die pad 41 (through the short circuit path). This enables an increase in the junction withstand voltage of the diode D to be achieved simply by exploiting the field plate effect.

Note that although as illustrated in FIG. 4 the substrate 2 is bonded onto the die pad 41 of the lead 40 in the semiconductor device 1 according to the present exemplary embodiment, a wiring board may be employed instead of the die pad 41, and the substrate 2 may be bonded onto this wiring board. Of course, wiring electrically connected to the substrate-support 20 would be arranged in at least a region of the wiring board opposing the diode D.

### Third Exemplary Embodiment

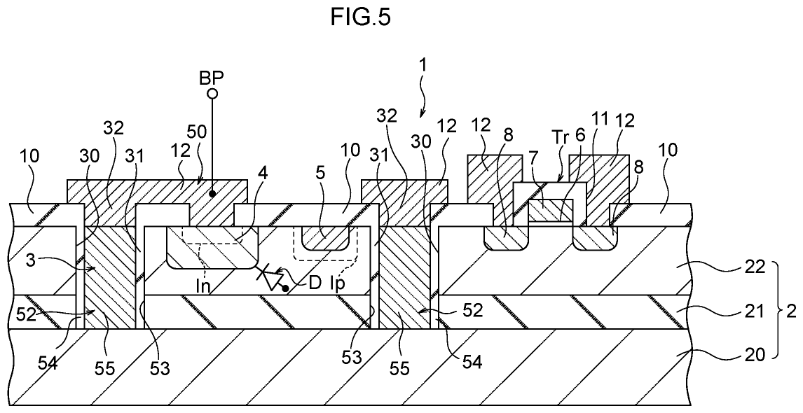

Explanation follows regarding a semiconductor device according to a third exemplary embodiment of the present invention, with reference to FIG. 5. A semiconductor device 1 according to the present exemplary embodiment is an example in which the structure of the second connection section 52 of the semiconductor device 1 according to the second exemplary embodiment has been modified.

As illustrated in FIG. 5, the semiconductor device 1 according to the present exemplary embodiment includes a second connection section 52 with a different structure to the structure of the second connection section 52 of the semiconductor device 1 according to the second exemplary embodiment. The second connection section 52 includes a penetrating section 53 and a penetrating conductor 55. The second connection section 52 is configured including the penetrating conductor 55 on a path that electrically connects the cathode region of the diode D and the substrate-support 20 of the substrate 2.

The penetrating section 53 is in communication with the trench 30 of the element isolation region 3 on the insulation layer 21 side of the substrate 2, and is configured as a through hole or a penetrating groove that extends from the surface of the insulation layer 21 at least as far as the surface of the substrate-support 20. Namely, the penetrating section 53 may be configured by plural through holes arranged at a prescribed spacing along an extension direction of the trench 30, or may be configured as a penetrating groove that extends so as to surround the periphery of the diode D similarly to the trench 30.

In this example, the penetrating section 53 is configured as a penetrating groove formed with the same planar profile as the planar profile of the trench 30. The penetrating section 53 may be formed at the same time as forming the trench 30 in the fabrication process of the semiconductor device 1.

An insulation body 54 that is similar to the insulation body 31 of the element isolation region 3 is arranged at inner walls of the penetrating section 53. The insulation body 31 and the insulation body 54 may be formed at the same stage of fabrication during the fabrication process.

The penetrating section 53 is filled by the penetrating conductor 55. One end portion of the penetrating conductor 55 is electrically connected to the conductor 32 of the element isolation region 3, and the other end portion of the penetrating conductor 55 is electrically connected to the surface of the substrate-support 20. In this example, the penetrating conductor 55 is integrally formed to the conductor 32 filling the trench 30 using the same material as the conductor 32.

In other words, the penetrating section 53 of the second connection section 52 is configured by simply extending the trench 30 of the element isolation region 3 as far as the surface of the substrate-support 20, and the penetrating conductor 55 is configured by filling as far as the inside of the penetrating section 53 with the conductor 32 of the element isolation region 3. Namely, the fabrication process of the second connection section 52 utilizes the fabrication process of the element isolation region 3, and there is no need to add an additional fabrication process in order to realize the second connection section 52.

Since the second connection section 52 is arranged surrounding the periphery of the diode D similarly to the element isolation region 3, the second connection section 52 is arranged in close proximity to the diode D.

Operation and Advantageous Effects of Present Exemplary Embodiment

The semiconductor device 1 according to the present exemplary embodiment is capable of obtaining similar operation and advantageous effects to the operation and advantageous effects obtained by the semiconductor device 1 according to the second exemplary embodiment.

Furthermore, as illustrated in FIG. 5, the semiconductor device 1 according to the present exemplary embodiment includes the second connection section 52. The second connection section 52 includes the penetrating section 53 and the penetrating conductor 55. The penetrating section 53 is in communication with the insulation layer 21 side of the trench 30 of the element isolation region 3, and extends from the surface of the insulation layer 21 as far as the substrate-support 20. The penetrating section 53 is filled by the penetrating conductor 55. The one end portion of the penetrating conductor 55 is electrically connected to the conductor 32 of the trench 30, and the other end portion of the penetrating conductor 55 is electrically connected to the substrate-support 20. The second connection section 52 is configured including a path including the penetrating conductor 55.

Thus, supposing a positive surge voltage were to be applied to the cathode region (n-type semiconductor region 4) of the diode D, the surge voltage would also be applied to the conductor 32 filling the trench 30 of the element isolation region 3. The surge voltage would also be applied to the substrate-support of the substrate 2 through the penetrating conductor 55 filling the penetrating section 53 of the second connection section 52. This enables an increase in the junction withstand voltage of the diode D to be simply achieved by exploiting the field plate effect.

In addition thereto, the surge voltage can be instantly applied to the substrate-support 20 via the short path that is directly below the element isolation region 3 arranged surrounding the periphery of the diode D and that is in close proximity to the diode D.

Supplementary Explanation of Above Exemplary Embodiments

The present invention is not limited to the above exemplary embodiments, and for example modifications such as those described below may be implemented within a range not departing from the spirit of the present invention.

In the substrate of the semiconductor device of the present invention, the substrate-support is not limited to being a monocrystalline silicon substrate, and as long as the substrate is conductive, a metal substrate, a compound semiconductor substrate, or the like may be employed therefore.

Moreover, in the present invention any element including a p-n junction diode may be employed as the protected element, such as an IGFET, a bipolar transistor, or a diffusion resistor. Specifically, a diode is formed at the p-n junction between one main electrode of an IGFET and the active layer. In cases in which a bipolar transistor is employed, a diode is formed at the p-n junction between a base region (active layer) and an emitter region or a collector region. In cases in which a diffusion resistor is employed, a diode is formed at the p-n junction between the diffusion resistor and the active layer.

Furthermore, in the present invention, a protected element may be constructed by two or more elements, such as a combination of a diode and an IGFET, or a combination of a diffusion resistor and an IGFET.

The entire content of the disclosure of Japanese Patent Application No. 2018-135261 filed on Jul. 18, 2018 is incorporated by reference in the present specification.

1. A semiconductor device comprising:
a protected element that is configured to include a p-n junction diode between an anode region and a cathode region, and arranged in an active layer of a substrate including the active layer formed over a conductive substrate-support with an insulation layer interposed between the active layer and the substrate-support;
an element isolation region that is configured to include a trench extending from a surface of the active layer as far as the insulation layer and surrounding a periphery of the p-n junction diode, an insulation body arranged on a side wall of the trench, and a conductor filling the trench such that the insulation body is interposed between the conductor and the trench; and
a first connection section electrically connecting the cathode region to the conductor.

2. The semiconductor device of claim 1, wherein the first connection section is configured by wiring arranged on the cathode region and on the conductor.

3. The semiconductor device of claim 1, further comprising a second connection section that electrically connects the cathode region to the substrate-support.

4. The semiconductor device of claim 3, further comprising a semiconductor element arranged in the active layer in a separate region to the protected element, the semiconductor element being any one out of an insulated-gate field-effect transistor, a bipolar transistor, a diffusion resistor, or a metal-insulator-semiconductor capacitor.

5. The semiconductor device of claim 3, further comprising:
an external terminal that is arranged on the substrate and electrically connected to the cathode region;
a die pad or wiring board that is mounted with the substrate and electrically connected to the substrate-support; and
a lead electrically that is connected to the external terminal through a wire; wherein
the second connection section is configured to include a path electrically connecting the lead either to the die pad or to the wiring board.

6. The semiconductor device of claim 3, wherein the second connection section includes:
a penetrating section extending from a surface of the insulation layer to the substrate-support so as to be in communication with the insulation layer side of the trench; and
a penetrating conductor filling the penetrating section such that one end portion of the penetrating conductor is electrically connected to the conductor and another end portion of the penetrating conductor is electrically connected to the substrate-support; wherein
the second connection section is configured to include a path including the penetrating conductor.
